(19) United States
(12) Patent Application Publication
(10) Pub. No.: US 2024/0267021 A1
(43) Pub. Date: Aug. 8, 2024

(54) ACOUSTIC WAVE DEVICE AND METHOD OF MANUFACTURING ACOUSTIC WAVE DEVICE

(71) Applicant: Murata Manufacturing Co., Ltd., Nagaokakyo-shi (JP)

(72) Inventors: Takashi YAMANE, Nagaokakyo-shi (JP); Hisashi YAMAZAKI, Nagaokakyo-shi (JP)

(21) Appl. No.: 18/626,361

(22) Filed: Apr. 4, 2024

Related U.S. Application Data
(63) Continuation of application No. PCT/JP2022/037499, filed on Oct. 6, 2022.
(60) Provisional application No. 63/253,598, filed on Oct. 8, 2021.

(51) Int. Cl. H03H 9/10; H03H 3/02; H03H 9/02; H03H 9/05; H03H 9/17

(52) U.S. Cl. CPC H03H 9/105; H03H 3/02; H03H 9/02031; H03H 9/02228; H03H 9/0523; H03H 9/173; H03H 9/176

(57) ABSTRACT

An acoustic wave device includes a first substrate, a piezoelectric layer including first and second main surfaces facing a thickness direction of the first substrate, the first main surface facing the first substrate, a functional electrode on at least one of the first or second main surfaces, a second substrate including a third main surface and a fourth main surface facing the thickness direction and a through-hole penetrating from the third main surface to the fourth main surface, the third main surface facing the second main surface of the piezoelectric layer, a via electrode in the through-hole, a wiring layer between the piezoelectric layer and the second substrate and electrically connecting the functional electrode and the via electrode, and an etching stop layer between the via electrode and the wiring layer and including a metal material with an etching rate lower than that of the second substrate.

### CROSS REFERENCE TO RELATED APPLICATIONS

This application claims the benefit of priority to Provisional Application No. 63/253,598 filed on Oct. 8, 2021 and is a Continuation Application of PCT Application No. PCT/JP2022/037499 filed on Oct. 6, 2022. The entire contents of each application are hereby incorporated herein by reference.

### BACKGROUND OF THE INVENTION

### 1. Field of the Invention

The present disclosure relates to acoustic wave devices each including a piezoelectric layer including lithium niobate or lithium tantalate, and methods of manufacturing acoustic wave devices.

### 2. Description of the Related Art

Japanese Unexamined Patent Application Publication No. 2012-257019 describes an acoustic wave device.

### SUMMARY OF THE INVENTION

In the case where the acoustic wave device is in wafer-level packaging by covering an electrode with a Si substrate (second substrate), a through-hole is formed in the Si substrate (second substrate) and the electrode is extended via the through-hole. Since the Si substrate (second substrate) has a first surface facing the electrode and a second surface facing the opposite side, conventionally, the through-hole is formed from the second surface of the Si substrate (second substrate) by dry etching. In addition, in the dry etching, the etching time is adjusted while detecting the position of the bottom surface of the through-hole by emission spectrometry. Therefore, the shape and depth of the through-hole vary.

Example embodiments of the present invention provide acoustic wave devices and methods for manufacturing same, in each of which, a shape and a depth of a through-hole are stabilized.

An acoustic wave device according to an aspect of an example embodiment of the present invention includes a first substrate, a piezoelectric layer including one main surface and another main surface facing a thickness direction of the first substrate, the one main surface facing the first substrate, a functional electrode provided on at least one of the one main surface and the another main surface of the piezoelectric layer, a second substrate including a first main surface and a second main surface facing the thickness direction and a through-hole penetrating from the first main surface to the second main surface, the first main surface facing the another main surface of the piezoelectric layer, a via electrode in the through-hole, a wiring layer between the piezoelectric layer and the second substrate and electrically connecting the functional electrode and the via electrode, and an etching stop layer between the via electrode and the wiring layer, in which the etching stop layer includes a metal material with an etching rate lower than an etching rate of the second substrate.

An acoustic wave device according to another aspect of an example embodiment of the present invention includes a first substrate, a piezoelectric layer including one main surface and another main surface facing a thickness direction of the first substrate, the one main surface facing the first substrate, a functional electrode provided on at least one of the one main surface and the another main surface of the piezoelectric layer, a second substrate being a silicon substrate and including a first main surface and a second main surface facing the thickness direction and a through-hole penetrating from the first main surface to the second main surface, the first main surface facing the another main surface of the piezoelectric layer, a via electrode in the through-hole, a wiring layer between the piezoelectric layer and the second substrate and electrically connecting the functional electrode and the via electrode, and an etching stop layer between the via electrode and the wiring layer, in which a metal material of the etching stop layer is any one of Ti, AlCu, Pt, or Cu.

A method of manufacturing an acoustic wave device according to another aspect of an example embodiment of the present invention includes forming a through-hole in an object by dry etching, in which the object includes a first substrate, a piezoelectric layer including one main surface and another main surface facing a thickness direction of the first substrate, the one main surface facing the first substrate, a functional electrode provided on at least one of the one main surface and the another main surface of the piezoelectric layer, a second substrate including a first main surface and a second main surface facing the thickness direction, the first main surface facing the another main surface of the piezoelectric layer, a wiring layer between the piezoelectric layer and the second substrate, and an etching stop layer between the wiring layer and the first main surface and including a metal material with an etching rate lower than an etching rate of the second substrate, and the through-hole is formed in the second main surface of the second substrate to at least partially overlap the etching stop layer in plan view.

A method of manufacturing an acoustic wave device according to another aspect of an example embodiment of the present invention includes forming a through-hole in an object by dry etching, in which the object includes a first substrate, a piezoelectric layer including one main surface and another main surface facing a thickness direction of the first substrate, the one main surface facing the first substrate, a functional electrode provided on at least one of the one main surface and the another main surface of the piezoelectric layer, a second substrate including a first main surface and a second main surface facing the thickness direction, the first main surface facing the another main surface of the piezoelectric layer, a wiring layer between the piezoelectric layer and the second substrate, and an etching stop layer arranged between the wiring layer and the first main surface and including a metal material of any of Ti, AlCu, Pt, or Cu, and the through-hole is formed in the second main surface of the second substrate to at least partially overlap the etching stop layer in plan view.

According to example embodiments of the present disclosure, the shape and depth of the through-hole are stabilized.

### BRIEF DESCRIPTION OF THE DRAWINGS

FIG. 1A is a perspective view of an acoustic wave device of an example embodiment of the present invention.

FIG. 1B is a plan view illustrating a structure of electrodes of an example embodiment of the present invention.

FIG. 2 is a cross-sectional view of a portion taken along line II-II of FIG. 1A.

FIG. 3A is a schematic cross-sectional view for explaining a Lamb wave propagating through a piezoelectric layer of a comparative example.

FIG. 3B is a schematic cross-sectional view for explaining a bulk wave in a first-order thickness-shear mode propagating through the piezoelectric layer of each example embodiment of the present invention.

FIG. 4 is a schematic cross-sectional view for explaining an amplitude direction of the bulk wave in the first-order thickness-shear mode propagating through the piezoelectric layer of each example embodiment of the present invention.

FIG. 5 is an explanatory diagram illustrating an example of resonance characteristics of an acoustic wave device of an example embodiment of the present invention.

FIG. 6 is an explanatory diagram illustrating a relationship between d/2p and a fractional bandwidth of a resonator in the acoustic wave device of each example embodiment of the present invention, when p is a center-to-center distance between adjacent electrodes to each other or the average distance of the center-to-center distance, and d is the average thickness of the piezoelectric layer.

FIG. 7 is a plan view illustrating an example in which a pair of electrodes are provided in an acoustic wave device of an example embodiment of the present invention.

FIG. 8 is a reference diagram illustrating an example of resonance characteristics of an acoustic wave device of an example embodiment of the present invention.

FIG. 9 is a diagram illustrating a relationship between the fractional bandwidth and a phase rotation amount of spurious impedance normalized by 180 degrees as the magnitude of spurious emission when a large number of acoustic wave resonators are provided according to each of the example embodiments of the present invention.

FIG. 10 is a diagram illustrating a relationship between d/2p, a metallization ratio MR, and the fractional bandwidth.

FIG. 11 is a diagram illustrating a map of a fractional bandwidth with respect to the Euler angles (0°, θ, ψ) of LiNbO₃ when d/p is made to approach 0 as much as possible.

FIG. 12 is a partially cutaway perspective view of an acoustic wave device of a modification of an example embodiment of the present invention.

FIG. 13 is a schematic view illustrating the configuration of an acoustic wave device of an example embodiment of the present invention.

FIG. 14 is a cross-sectional view illustrating a second substrate after a resist film forming step of an example embodiment of the present invention.

FIG. 15 is a cross-sectional view illustrating the second substrate after an etching stop layer forming step of an example embodiment of the present invention.

FIG. 16 is a cross-sectional view illustrating the second substrate after a first wiring layer forming step of an example embodiment of the present invention.

FIG. 17 is a cross-sectional view illustrating the second substrate after a resist film removing step of an example embodiment of the present invention.

FIG. 18 is a cross-sectional view illustrating an intermediate product after a bonding step of an example embodiment of the present invention.

FIG. 19 is a cross-sectional view illustrating the intermediate product after a through-hole forming step of an example embodiment of the present invention.

FIG. 20 is a cross-sectional view illustrating the intermediate product after an insulating film forming step of an example embodiment of the present invention.

FIG. 21 is a cross-sectional view illustrating the intermediate product after a seed layer laminating/resist film forming/plate processing step of an example embodiment of the present invention.

FIG. 22 is a cross-sectional view illustrating the intermediate product after a resist film removing/window forming step of an example embodiment of the present invention.

FIG. 23 is a cross-sectional view illustrating the intermediate product after a dicing step of an example embodiment of the present invention.

FIG. 24 is a cross-sectional view illustrating the intermediate product after soldering of an example embodiment of the present invention.

FIG. 25 is a cross-sectional view illustrating an acoustic wave device after a singulation/polishing step of an example embodiment of the present invention.

### DETAILED DESCRIPTION OF THE EXAMPLE EMBODIMENTS

Hereinafter, example embodiments of the present disclosure will be described in detail with reference to the drawings. Note that the present disclosure is not limited to the example embodiments. Note that each example embodiment described in the present disclosure is merely an example, and in modifications and second and subsequent example embodiments in which partial replacement or combination of configurations is possible between different example embodiments, description of matters common to the first example embodiment will be omitted, and only different points will be described. In particular, similar effects of similar configurations will not be described in each example embodiment.

### EXAMPLE EMBODIMENT

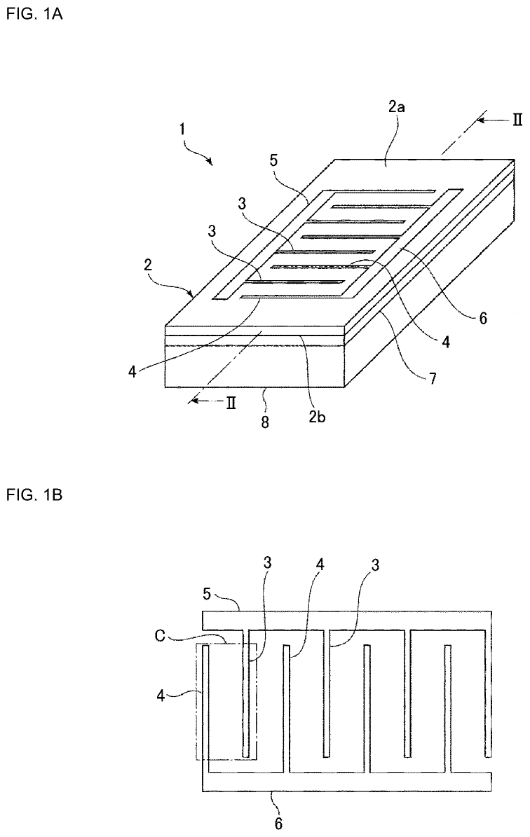

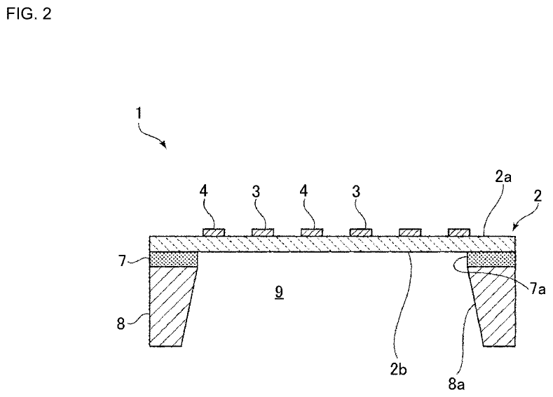

FIG. 1A is a perspective view of an acoustic wave device of an example embodiment. FIG. 1B is a plan view illustrating the structure of electrodes of the present example embodiment. FIG. 2 is a cross-sectional view of a portion taken along line II-II of FIG. 1A. First, a basic configuration of the acoustic wave device will be described. An acoustic wave device of the present example embodiment includes a piezoelectric layer made of lithium niobate or lithium tantalate, and a first electrode and a second electrode facing each other in a direction intersecting a thickness direction of the piezoelectric layer. The bulk wave in a first-order thickness-shear mode is used in the acoustic wave device. Additionally, in a second aspect of an example embodiment of the present invention, the first electrode and the second electrode are adjacent electrodes to each other, and when the thickness of the piezoelectric layer is defined as d and the center-to-center distance between the first electrode and the second electrode is defined as p, d/p is equal to or less than about 0.5, for example. Thus, the acoustic wave device can have a high Q value even when the size thereof is reduced. In addition, the acoustic wave device uses a Lamb wave as a plate wave. Thus, resonance characteristics by the Lamb wave can be obtained.

In detail, as illustrated in FIGS. 1A, 1B, and FIG. 2, an acoustic wave device 1 includes a piezoelectric layer 2 made of LiNbO₃. The piezoelectric layer 2 may be made of LiTaO₃. The cut angle of LiNbO₃ and LiTaO₃ is Z-cut in the present example embodiment, but may be rotated Y-cut or X-cut. Preferably, a propagation orientation of Y propagation and X propagation of about ±30° is preferred. The thickness of the piezoelectric layer 2 is not particularly limited, but is preferably equal to or more than about 50 nm and equal to or less than about 1000 nm, for example, in order to effectively excite the first-order thickness-shear mode. The piezoelectric layer 2 has one main surface 2b and another main surface 2a facing each other. An electrode 3 and an electrode 4 are provided on the other main surface 2a.

Here, the electrode 3 is an example of a “first electrode”, and the electrode 4 is an example of a “second electrode”. In FIGS. 1A and 1B, the plurality of electrodes 3 is a plurality of first electrode fingers connected to a first busbar 5. The plurality of electrodes 4 is a plurality of second electrode fingers connected to a second busbar 6. The plurality of electrodes 3 and the plurality of electrodes 4 are interdigitated with each other.

The electrode 3 and the electrode 4 have a rectangular or substantially rectangular shape and a length direction. The electrode 3 and the electrode 4 adjacent to the electrode 3 face each other in a direction perpendicular or substantially perpendicular to the length direction. The plurality of electrodes 3 and 4 and the first and second busbars 5 and 6 define interdigital transducer (IDT) electrodes.

The length direction of the electrodes 3 and 4 and the direction perpendicular or substantially perpendicular to the length direction of the electrodes 3 and 4 are each directions intersecting the thickness direction of the piezoelectric layer 2. Therefore, it can be said that the electrode 3 and the electrode 4 adjacent to the electrode 3 face each other in a direction intersecting the thickness direction of the piezoelectric layer 2. In addition, the length direction of the electrodes 3 and 4 may be exchanged with the direction perpendicular or substantially perpendicular to the length direction of the electrodes 3 and 4 illustrated in FIGS. 1A and 1B. That is, in FIGS. 1A and 1B, the electrodes 3 and 4 may be extended in a direction in which the first busbar 5 and the second busbar 6 extend. In this case, the first busbar 5 and the second busbar 6 extend in a direction in which the electrodes 3 and 4 extend in FIGS. 1A and 1B.

A plurality of pairs of structures each having the electrode 3 connected to one potential and the electrode 4 connected to the other potential adjacent to each other is provided in a direction perpendicular or substantially perpendicular to the length direction of the electrode 3 and the electrode 4. Here, the electrode 3 and the electrode 4 being adjacent to each other does not mean the case where the electrode 3 and the electrode 4 are arranged so as to be in direct contact with each other, but means the case where the electrode 3 and the electrode 4 are arranged with a gap therebetween. In addition, when the electrode 3 and the electrode 4 are adjacent to each other, no electrode connected to a hot electrode or a ground electrode, including the other electrodes 3 and 4, is arranged between the electrode 3 and the electrode 4. The number of pairs is not necessary an integer pair, and may be 1.5 pairs, 2.5 pairs, or the like.

The center-to-center distance between the electrode 3 and the electrode 4, that is, the pitch is preferably in the range of equal to or more than about 1 μm and equal to or less than about 10 μm, for example. In addition, the center-to-center distance between the electrode 3 and the electrode 4 is a distance between the center of the width dimension of the electrode 3 in the direction perpendicular or substantially perpendicular to the length direction of the electrode 3 and the center of the width dimension of the electrode 4 in the direction perpendicular or substantially perpendicular to the length direction of the electrode 4.

Further, when at least one of the electrode 3 and the electrode 4 is provided in plural number (there are 1.5 or more pairs of electrode sets when the electrodes 3 and 4 are provided as a pair of electrode sets), the center-to-center distance between the electrode 3 and the electrode 4 refers to the average value of the center-to-center distances between the adjacent electrodes 3 and 4 among the 1.5 or more pairs of electrodes 3 and 4.

In addition, the widths of the electrodes 3 and 4, that is, the dimensions of the electrodes 3 and 4 in a facing direction are preferably in the range of equal to or more than about 150 nm and equal to or less than about 1000 nm, for example. Note that the center-to-center distance between the electrode 3 and the electrode 4 is a distance between the center of the dimension (width dimension) of the electrode 3 in the direction perpendicular or substantially perpendicular to the length direction of the electrode 3 and the center of the dimension (width dimension) of the electrode 4 in the direction perpendicular or substantially perpendicular to the length direction of the electrode 4.

Additionally, in the present example embodiment, since the Z-cut piezoelectric layer is used, the direction perpendicular or substantially perpendicular to the length direction of the electrode 3 and the electrode 4 is a direction perpendicular or substantially perpendicular to a polarization direction of the piezoelectric layer 2. This is not the case when a piezoelectric material having a different cut angle is used as the piezoelectric layer 2. Here, the term “perpendicular” is not limited to the case of being strictly perpendicular, and may be substantially perpendicular (the angle defined by the direction perpendicular or substantially perpendicular to the length direction of the electrodes 3 and 4 and the polarization direction is, for example, about 90°±10°).

A support 8 is laminated on the one main surface 2b side of the piezoelectric layer 2 with an insulating layer 7 interposed therebetween. The insulating layer 7 and the support 8 have a frame shape, and have opening portions 7a and 8a as illustrated in FIG. 2. Thus, a cavity portion (air gap) 9 is formed.

The cavity portion 9 is provided so as not to hinder the vibration of an excitation region C of the piezoelectric layer 2. Therefore, the above support 8 is laminated on the one main surface 2b with the insulating layer 7 interposed therebetween at a position not overlapping the portion where at least the pair of electrodes 3 and 4 are provided. Note that the insulating layer 7 need not be provided. Therefore, the support 8 can be laminated directly or indirectly on the one main surface 2b of the piezoelectric layer 2.

The insulating layer 7 is made of silicon oxide. However, in addition to silicon oxide, an appropriate insulating material such as silicon oxynitride or alumina can be used. The support 8 is made of Si. The plane orientation of Si in the surface on the piezoelectric layer 2 side may be (100), (110), or (111). Preferably, Si having a high resistance of equal to or more than about 4 kΩ is desirable.

However, also the support 8 may be made of an appropriate insulating material or semiconductor material. As the material of the support 8, for example, a piezoelectric material such as aluminum oxide, lithium tantalate, lithium niobate, or quartz, various ceramics such as alumina, magnesia, sapphire, silicon nitride, aluminum nitride, silicon carbide, zirconia, cordierite, mullite, steatite, or forsterite, a dielectric material such as diamond or glass, or a semiconductor such as gallium nitride can be used.

The plurality of electrodes 3 and 4, the first busbar 5, and the second busbar 6 described above are made of an appropriate metal or alloy such as Al or an AlCu alloy. In the present example embodiment, the electrodes 3 and 4, the first busbar 5, and the second busbar 6 have a structure in which an Al film is laminated on a Ti film. Note that an adhesion layer other than the Ti film may be used.

In driving, an AC voltage is applied between the plurality of electrodes 3 and the plurality of electrodes 4. More specifically, an AC voltage is applied between the first busbar 5 and the second busbar 6. Thus, it is possible to obtain resonance characteristics using a bulk wave in the first-order thickness-shear mode excited in the piezoelectric layer 2.

Additionally, in the acoustic wave device 1, d/p is equal to or less than about 0.5, for example, when d is the thickness of the piezoelectric layer 2, and p is the center-to-center distance between any adjacent electrodes 3 and 4 among the plurality of pairs of electrodes 3 and 4. Therefore, the above bulk wave of the first-order thickness-shear mode is effectively excited, and favorable resonance characteristics can be obtained. More preferably, d/p is equal to or less than about 0.24, for example, and in this case, even more favorable resonance characteristics can be obtained.

Note that in the case where at least one of the electrodes 3 and 4 is provided in plural number as in the present example embodiment, that is, there are 1.5 or more pairs of electrode 3 and 4 sets when the electrodes 3 and 4 are provided as a pair of electrode sets, the center-to-center distance p between the adjacent electrodes 3 and 4 is the average distance of the center-to-center distances between the respective adjacent electrodes 3 and 4.

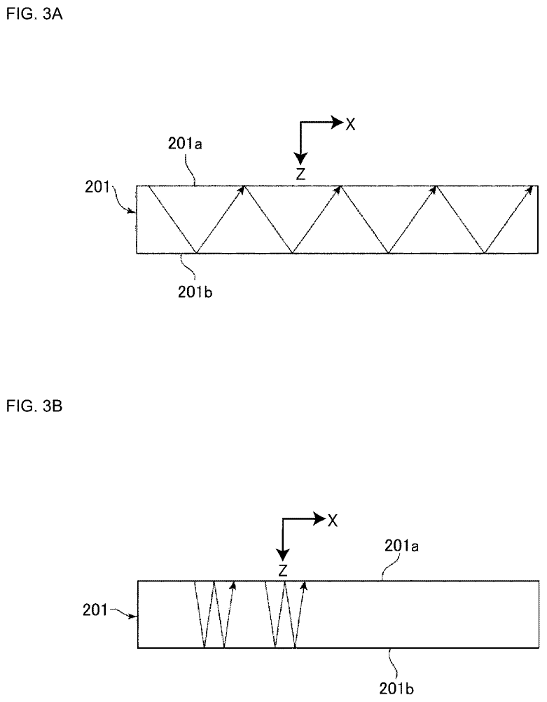

Since the acoustic wave device 1 of the present example embodiment has the above-described configuration, even when the number of pairs of the electrodes 3 and 4 is reduced in order to achieve miniaturization, the Q value is unlikely to be reduced. This is because the resonator does not require reflectors on both sides and has a small propagation loss. In addition, the reflector is not required because the bulk wave in the first-order thickness-shear mode is used. The difference between the Lamb wave used in the existing acoustic wave device and the bulk wave in the first-order thickness-shear mode will be described with reference to FIG. 3A and FIG. 3B.

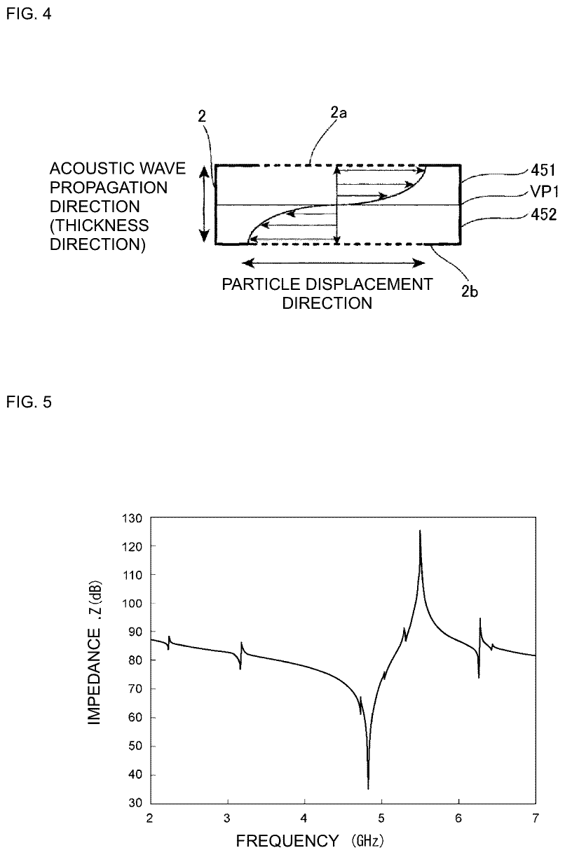

FIG. 3A is a schematic cross-sectional view for explaining a Lamb wave propagating through the piezoelectric layer of the comparative example. FIG. 3B is a schematic cross-sectional view for explaining a bulk wave in the first-order thickness-shear mode propagating through the piezoelectric layer of each example embodiment. FIG. 4 is a schematic cross-sectional view for explaining the amplitude direction of a bulk wave in the first-order thickness-shear mode propagating through the piezoelectric layer of each example embodiment.

FIG. 3A illustrates such an acoustic wave device as described in Japanese Unexamined Patent Application Publication No. 2012-257019, in which a Lamb wave propagates through a piezoelectric film. Here, the wave propagates in a piezoelectric film 201 as indicated by arrows. In the piezoelectric film 201 here, a first main surface 201a and a second main surface 201b face each other, and the thickness direction connecting the first main surface 201a and the second main surface 201b is a Z direction. An X direction is a direction in which electrode fingers of the IDT electrode are arranged. As illustrated in FIG. 3A, in the Lamb wave, the wave propagates in the X direction as illustrated in the figure. Although the piezoelectric film 201 vibrates as a whole because of the plate wave, the wave propagates in the X direction, and thus reflectors are arranged on both sides to obtain resonance characteristics. Therefore, the propagation loss of waves occurs, and when miniaturization is achieved, that is, when the number of pairs of electrode fingers is reduced, the Q value is reduced.

In contrast, as illustrated in FIG. 3B, in the acoustic wave device of the present example embodiment, since the vibration displacement is in a thickness-shear direction, the wave propagates substantially in the direction connecting the other main surface 2a and the one main surface 2b of the piezoelectric layer 2, that is, in the Z direction, and the wave resonates. That is, the X-direction component of the wave is significantly smaller than the Z-direction component. Since the resonance characteristic is obtained by the propagation of the wave in the Z direction, no reflector is required. Therefore, no propagation loss occurs when the wave propagates to the reflector. Therefore, even when the number of electrode pairs each including the electrode 3 and the electrode 4 is reduced to achieve miniaturization, the Q value is less likely to be reduced.

Note that as illustrated in FIG. 4, the amplitude direction of the bulk wave in the first-order thickness-shear mode is reversed between a first region 451 included in the excitation region C of the piezoelectric layer 2 and a second region 452 included in the excitation region C. FIG. 4 schematically illustrates a bulk wave in the case where a voltage is applied between the electrode 3 and the electrode 4 so that the electrode 4 has a higher potential than the electrode 3. The first region 451 is a region of the excitation region C between the other main surface 2a and a virtual plane VP1 that is perpendicular or substantially perpendicular to the thickness direction of the piezoelectric layer 2 and divides the piezoelectric layer 2 into two parts. The second region 452 is a region between the virtual plane VP1 and the one main surface 2b in the excitation region C.

As described above, in the acoustic wave device 1, at least one pair of electrodes including the electrode 3 and the electrode 4 is arranged, but since the acoustic wave device 1 does not propagate a wave in the X direction, the number of pairs of electrodes including the electrodes 3 and 4 is not necessary plural. That is, it is sufficient that at least one pair of electrodes is provided.

For example, the electrode 3 is an electrode connected to a hot potential, and the electrode 4 is an electrode connected to a ground potential. However, the electrode 3 may be connected to the ground potential, and the electrode 4 may be connected to the hot potential. In the present example embodiment, as described above, at least one pair of electrodes includes an electrode connected to the hot potential or an electrode connected to the ground potential, and no floating electrode is provided.

FIG. 5 is an explanatory diagram illustrating an example of resonance characteristics of the acoustic wave device of the present example embodiment. Note that examples of the design parameters of the acoustic wave device 1 having the resonance characteristics illustrated in FIG. 5 are as follows.
Piezoelectric layer 2: LiNbO₃ having Euler angles (0°, 0°, 90°)
Thickness of piezoelectric layer 2: 400 nm
Length of excitation region C: 40 μm
Number of pairs of electrodes 3 and 4: 21 pairs
Inter-electrode center distance between electrode 3 and electrode 4: 3 μm
Widths of electrode 3 and electrode 4: 500 nm d/p=0.133
Insulating layer 7: silicon oxide film having thickness of 1 μm
Support 8: Si

Note that the length of the excitation region C is a dimension of the excitation region C along the length direction of the electrode 3 and the electrode 4. In the present example embodiment, the inter-electrode distances of the electrode pairs each including the electrode 3 and the electrode 4 were made all equal in the plurality of pairs. That is, the electrodes 3 and the electrodes 4 were arranged at an equal pitch.

As is clear from FIG. 5, although the reflector is not provided, a favorable resonance characteristic with a fractional bandwidth of about 12.5%, for example, is obtained.

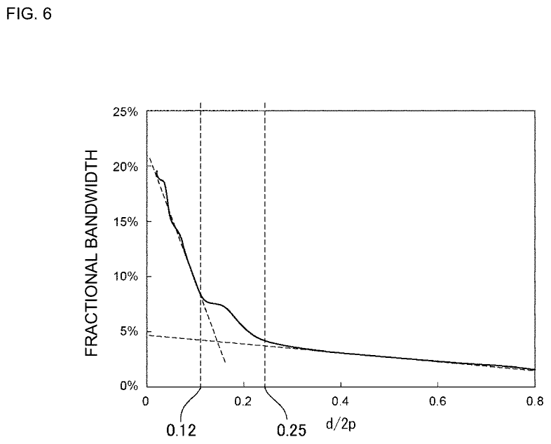

As described above, in the present example embodiment, d/p is equal to or less than about 0.5, and more preferably equal to or less than about 0.24, for example, when d is the thickness of the piezoelectric layer 2 and p is the center-to-center distance between the electrode 3 and the electrode 4. This will be described with reference to FIG. 6.

A plurality of acoustic wave devices was obtained in the same manner as the acoustic wave device having the resonance characteristics illustrated in FIG. 5, except that d/2p was changed. FIG. 6 is an explanatory diagram illustrating a relationship between d/2p and the fractional bandwidth of the resonator in the acoustic wave device of the example embodiment, when p is the center-to-center distance between adjacent electrodes or the average distance of the center-to-center distance, and d is the average thickness of the piezoelectric layer.

As is clear from FIG. 6, when d/2p exceeds about 0.25, that is, when d/p>about 0.5 is satisfied, the fractional bandwidth is less than about 5% even when d/p is adjusted, for example. In contrast, when d/2p≤0.25, that is, d/p≤about 0.5 is satisfied, the fractional bandwidth can be increased to equal to or more than about 5% by changing d/p within the range, for example, that is, resonators having a high coupling coefficient can be provided. In addition, when d/2p is equal to or less than about 0.12, that is, when d/p is equal to or less than about 0.24, the fractional bandwidth can be increased to equal to or more than about 7%, for example. In addition, by adjusting d/p within this range, a resonator having a wider fractional bandwidth can be obtained, and a resonator having a higher coupling coefficient can be realized. Therefore, it is understood that a resonator having a high coupling coefficient utilizing the bulk wave in the first-order thickness-shear mode can be configured by setting d/p to be equal to or less than about 0.5, for example, as in the second aspect of an example embodiment of the present invention of the present application.

Note that as described above, at least one pair of electrodes may be one pair, and the above p is defined as the center-to-center distance between the adjacent electrodes 3 and 4 in the case of one pair of electrodes. Additionally, in the case of equal to or more than 1.5 pairs of electrodes, the average distance of the center-to-center distances between the adjacent electrodes 3 and 4 may be p. In addition, when the piezoelectric layer 2 has a variation in thickness, the thickness d of the piezoelectric layer may be obtained from the average value of the thicknesses.

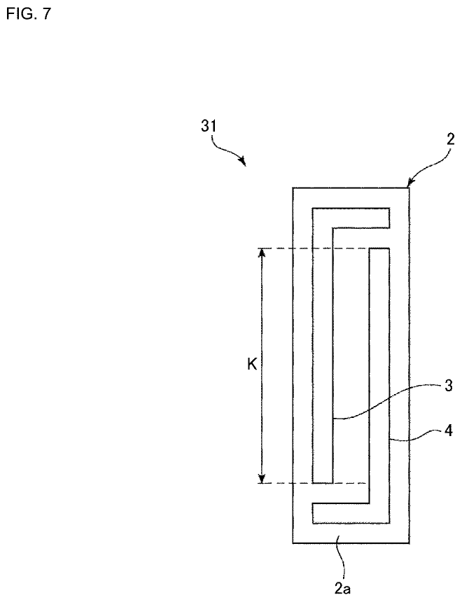

FIG. 7 is a plan view illustrating an example in which a pair of electrodes are provided in the acoustic wave device of the present example embodiment. In an acoustic wave device 31, a pair of electrodes including the electrode 3 and the electrode 4 are provided on the other main surface 2a of the piezoelectric layer 2. Note that in FIG. 7, K is the intersecting width. As described above, in an acoustic wave device according to an example embodiment of the present invention, the number of pairs of electrodes may be one. Also in this case, when the above d/p is equal to or less than about 0.5, for example, the bulk wave in the first-order thickness-shear mode can be effectively excited.

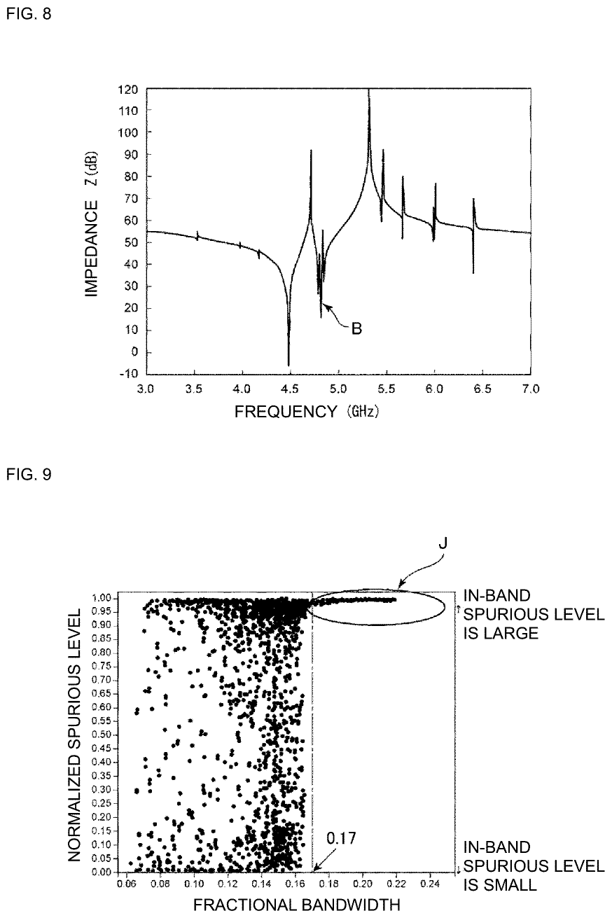

In the acoustic wave device 1, preferably, it is desirable that the metallization ratio MR of the adjacent electrodes 3 and 4 with respect to the excitation region, which is a region where any adjacent electrodes 3 and 4 among the plurality of electrodes 3 and 4 overlap each other when viewed in a direction in which the adjacent electrodes 3 and 4 face each other, satisfy MR about 1.75 (d/p)+0.075, for example. In this case, spurious emission can be effectively reduced. This will be described with reference to FIG. 8 and FIG. 9.

FIG. 8 is a reference diagram illustrating an example of resonance characteristics of the acoustic wave device of an example embodiment of the present invention. Spurious emission indicated by an arrow B appears between the resonant frequency and the anti-resonant frequency. FIG. 9 is a diagram illustrating a relationship between the fractional bandwidth and a phase rotation amount of spurious impedance normalized by 180 degrees as the magnitude of the spurious emission when a large number of acoustic wave resonators are provided according to each of the example embodiments. Note that d/p=about 0.08 and the Euler angles of LiNbO₃ were (0°, 0°, 90°), for example. In addition, the metallization ratio MR was set to about 0.35, for example.

The metallization ratio MR will be explained with reference to FIG. 1B. In the electrode structure illustrated in FIG. 1B, when attention is paid to the pair of electrodes 3 and 4, it is assumed that only the pair of electrodes 3 and 4 are provided. In this case, the portion surrounded by a dashed-dotted line C is the excitation region. The excitation region includes a region in the electrode 3 overlapping the electrode 4, a region in the electrode 4 overlapping the electrode 3, and a region between the electrode 3 and the electrode 4 where the electrode 3 and the electrode 4 overlap each other, when the electrode 3 and the electrode 4 are viewed in a direction perpendicular or substantially perpendicular to the length direction of the electrode 3 and the electrode 4, that is, in the facing direction.

The area of the electrodes 3 and 4 in the excitation region C with respect to the area of the excitation region is the metallization ratio MR. That is, the metallization ratio MR is the ratio of the area of the metallization portion with respect to the area of the excitation region. Note that when a plurality of pairs of electrodes is provided, the ratio of the metallization portions included in the entire excitation region with respect to the total area of the excitation regions may be defined as MR.

FIG. 9 is a diagram illustrating a relationship between the fractional bandwidth and the phase rotation amount of the spurious impedance normalized by 180 degrees as the magnitude of the spurious emission when a large number of acoustic wave resonators are provided according to the present example embodiment. Note that the fractional bandwidth was adjusted by changing variously the film thickness of the piezoelectric layer and the dimensions of the electrodes. In addition, although FIG. 8 illustrates the results obtained when the piezoelectric layer formed of Z-cut LiNbO₃ is used, the same tendency is obtained when a piezoelectric layer having another cut angle is used.

In the region surrounded by an ellipse J in FIG. 9, the spurious emission is as large as about 1.0, for example. As is clear from FIG. 9, when the fractional bandwidth exceeds about 0.17, that is, when the fractional bandwidth exceeds about 17%, a large spurious emission at a spurious level of about 1 or more appears in a pass band even when the parameters defining the fractional bandwidth are changed, for example. That is, as in the resonance characteristics illustrated in FIG. 8, the large spurious emission indicated by the arrow B appears in the band. Therefore, the fractional bandwidth is preferably equal to or less than about 17%, for example. In this case, the spurious emission can be reduced by adjusting the film thickness of the piezoelectric layer 2 and the dimensions of the electrode 3 and the electrode 4.

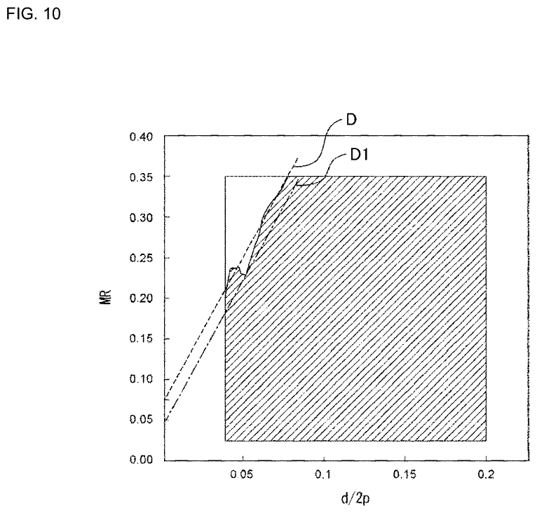

FIG. 10 is a diagram illustrating a relationship between d/2p, the metallization ratio MR, and the fractional bandwidth. In the above acoustic wave device, various acoustic wave devices having different d/2p and MR were formed, and the fractional bandwidth was measured. The hatched portion on the right side of a broken line D in FIG. 10 is a region where the fractional bandwidth is equal to or less than about 17%, for example. The boundary between the hatched region and the unhatched region is represented by MR=about 3.5 (d/2p)+0.075, for example. That is, MR=about 1.75 (d/p)+0.075, for example. Therefore, preferably, MR≤about 1.75 (d/p)+0.075 is satisfied, for example. In this case, the fractional bandwidth is easily set to equal to or less than about 17%, for example. More preferably, it is a region on the right side of MR=about 3.5 (d/2p)+0.05 indicated by a dashed-dotted line Dl in FIG. 10, for example. That is, when MR≤about 1.75 (d/p)+0.05 is satisfied, the fractional bandwidth can be reliably set to equal to or less than about 17%, for example.

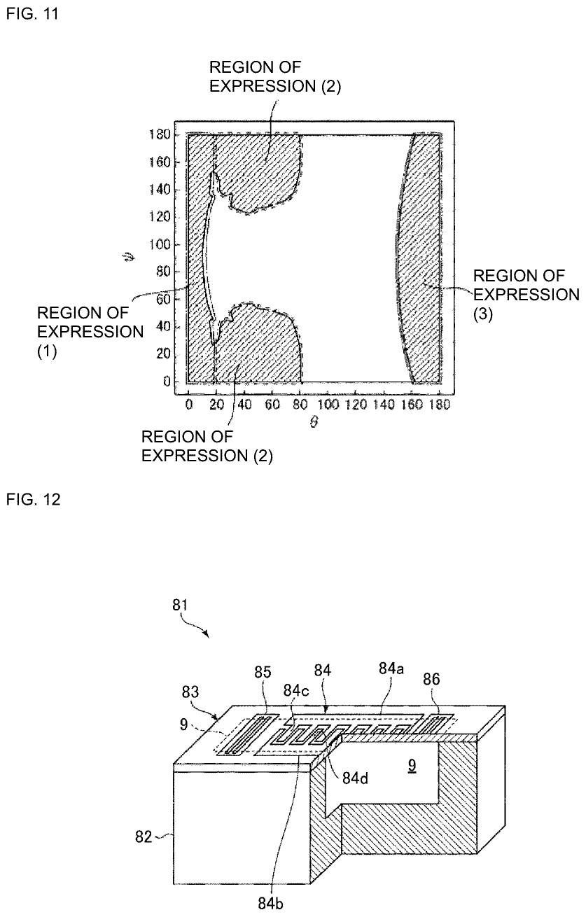

FIG. 11 is a diagram illustrating a map of the fractional bandwidth with respect to the Euler angles (0°, 0, $) of LiNbO₃ when d/p is made to approach 0 as much as possible. The hatched portion in FIG. 11 is a region where a fractional bandwidth of at least equal to or more than about 5% is obtained, for example. The range of this region is approximated to the range represented by the following Expression (1), Expression (2), and Expression (3).

(0°±10°, 0° to 20°, arbitraryψ) Expression (1)

(0°±10°, 20° to 80°, 0° to 60°(1−(θ−50)²/900)^{1/2}) or (0°±10°, 20° to 80°, [180°−60°(1−(θ−50)²/900)^{1/2}] to 180°) Expression (2)

(0°±10°, [180°−30°(1−(ψ−90)²/8100)^{1/2}] to 180°, arbitraryψ) Expression (3)

Therefore, the fractional bandwidth can be sufficiently increased when the Euler angles satisfy the above Expression (1), Expression (2), or Expression (3), which is preferable. The basic configuration of the acoustic wave device has been described above, but the present disclosure may be applied to an acoustic wave device 81 of the following modification.

FIG. 12 is a partially cutaway perspective view of an acoustic wave device of a modification. As illustrated in FIG. 12, the acoustic wave device 81 of the modification includes a support substrate 82. The support 8 (see FIG. 1A, etc.) is cut into a plate shape. The support substrate 82 of the support 8 is provided with a recess opened on the upper surface. A piezoelectric layer 83 is laminated on the support substrate 82. Thus, the cavity portion 9 is formed. An IDT electrode 84 is provided on the piezoelectric layer 83 above the cavity portion 9. A reflector 85 and a reflector 86 are provided on both sides of the IDT electrode 84 in the acoustic wave propagation direction.

In FIG. 12, the outer peripheral edge of the cavity portion 9 is indicated by a broken line. In this case, the IDT electrode 84 includes a first busbar 84a, a second busbar 84b, a plurality of electrodes 84c as first electrode fingers, and a plurality of electrodes 84d as second electrode fingers. The plurality of electrodes 84c is connected to the first busbar 84a. The plurality of electrodes 84d is connected to the second busbar 84b. The plurality of electrodes 84c and the plurality of electrodes 84d are interdigitated.

In the acoustic wave device 81, an alternating electric field is applied to the IDT electrode 84 on the cavity portion 9, and thus a Lamb wave as a plate wave is excited. Since the reflector 85 and the reflector 86 are provided on both sides, the resonance characteristics by the above Lamb wave can be obtained. As described above, the acoustic wave device of the present disclosure may use a plate wave. Next, the acoustic wave device of the present example embodiment will be described in detail.

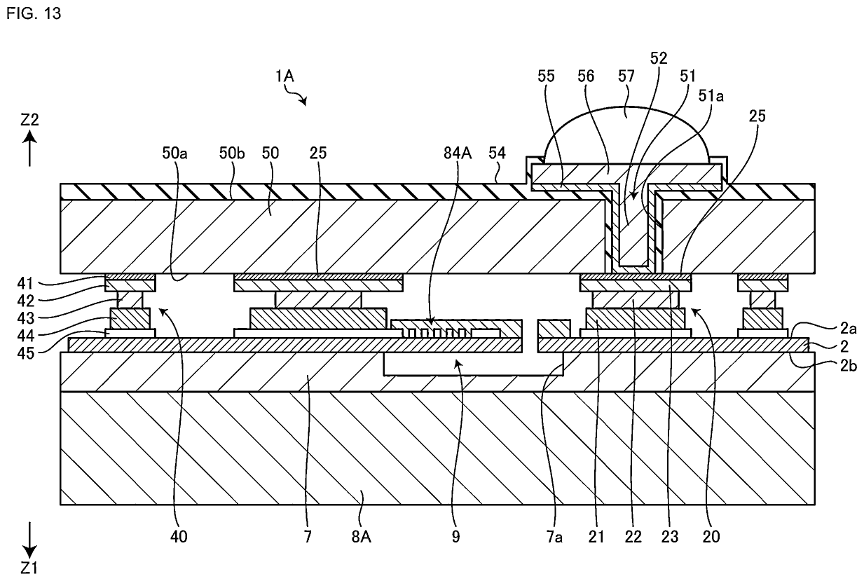

FIG. 13 is a schematic view illustrating the configuration of an acoustic wave device of the present example embodiment. As illustrated in FIG. 13, an acoustic wave device 1A includes a first substrate 8A, the piezoelectric layer 2, a functional electrode 84A, a second substrate 50, a via electrode 52, a wiring layer 20, and an etching stop layer 25.

The first substrate 8A is obtained by cutting the support 8 (see FIG. 1A, etc.) into a plate shape. The piezoelectric layer 2 has the one main surface 2b and the other main surface 2a facing the thickness direction of the first substrate 8A. The one main surface 2b faces the first substrate 8A. Hereinafter, a direction in which the one main surface 2b faces in the thickness direction of the first substrate 8A is referred to as a first thickness direction Z1. In addition, the direction opposite to the first thickness direction Z1 is referred to as a second thickness direction Z2.

The insulating layer 7 (see FIG. 1A, etc.) is provided between the first substrate 8A and the piezoelectric layer 2. Note that the insulating layer 7 may be referred to as an intermediate layer. In the present example embodiment, the opening portion 7a is provided in the center portion of the insulating layer 7. On the other hand, the opening portion 8a (see FIGS. 1A and 1B) is not provided in the first substrate 8A. Thus, the cavity portion 9 in the first thickness direction Z1 is covered with the first substrate 8A.

The functional electrode 84A is the IDT electrode 84 (see FIG. 12) and is provided on the other main surface 2a of the piezoelectric layer 2. Note that in the present disclosure, it may be provided on at least one of the one main surface 2b and the other main surface 2a of the piezoelectric layer 2.

The wiring layer 20 is arranged between the piezoelectric layer 2 and the second substrate 50. The wiring layer 20 electrically connects the functional electrode 84A and the via electrode 52. The wiring layer 20 includes an intermediate wiring layer 21, a second wiring layer 22, and a first wiring layer 23 that are laminated in order from the first thickness direction Z1. In other words, the wiring layer 20 includes the first wiring layer 23, the second wiring layer 22, and the intermediate wiring layer 21 that are laminated in order from the second substrate 50 side. The intermediate wiring layer 21 is electrically connected to the first busbar 84a and the second busbar 84b (see FIG. 12) of the functional electrode 84A.

The second wiring layer 22 is an Au layer. The first wiring layer 23 includes a plurality of layers made of different metals, and in the present example embodiment, the first wiring layer 23 includes a Ti layer, a Pt layer, and an Au layer that are laminated in order from the via electrode side (the second thickness direction Z2). In addition, the second wiring layer 22 is formed on the first substrate 8A side, and the first wiring layer 23 is formed on the second substrate 50 side. When the first substrate 8A and the second substrate 50 are bonded to each other, the Au layer of the second wiring layer 22 and the Au layer of the first wiring layer 23 are bonded to each other (Au—Au bonding).

The second substrate 50 is a silicon substrate made of Si. The second substrate 50 has a first main surface 50a and a second main surface 50b facing the thickness direction, and a through-hole 51 penetrating from the first main surface 50a to the second main surface 50b. The first main surface 50a faces the first thickness direction Z1. The second main surface 50b faces the second thickness direction Z2.

The through-hole 51 overlaps the wiring layer 20 when viewed from the thickness direction. An insulating layer 54 is provided in a side surface 51a of the through-hole 51. The insulating layer 54 is a silicon oxide film made of Si. In addition, the insulating layer 54 is provided on the second main surface 50b of the second substrate 50, the side surface of an under bump metal 56, and the edge portion of the surface of the under bump metal 56 in the second thickness direction Z2.

The via electrode 52 is arranged in the through-hole 51. The via electrode 52 overlaps the wiring layer 20 (first wiring layer 23) when viewed from the thickness direction. The etching stop layer 25 is arranged between the via electrode 52 and the wiring layer 20 (first wiring layer 23). The etching stop layer 25 is made of a metal material with an etching rate lower than that of the second substrate 50. In the present example embodiment, the second substrate 50 is a silicon substrate. Therefore, in the present example embodiment, the metal material of the etching stop layer 25 is formed of any of Ti, AlCu, Pt, and Cu. In addition, the etching stop layer 25 is laminated on the first wiring layer 23 in the second thickness direction Z2.

Note that in the present disclosure, the etching stop layer 25 may be made of a material other than Ti, AlCu, Pt, and Cu. That is, when the gas used in the dry etching is any one of C4F8 gas, CF4 gas, CHF3 gas, or SF6 gas, the etching stop layer 25 is not particularly limited as long as the etching rate of the etching stop layer 25 is lower than the etching rate of the silicon substrate (second substrate 50).

A seed layer 55 is arranged between the via electrode 52 and the etching stop layer 25 in the through-hole 51. Therefore, the via electrode 52 is electrically connected to the wiring layer 20 (first wiring layer 23) via the seed layer 55 and the etching stop layer 25.

The seed layer 55 includes a first metal layer (not illustrated) laminated on the etching stop layer 25 and a second metal layer (not illustrated) laminated on the first metal layer. From the viewpoint of adhesion and low resistance, the first metal layer of the seed layer 55 is formed of the same metal material as the etching stop layer 25. Note that in the present disclosure, the seed layer 55 may be formed such that the first metal layer is made of Ti and the second metal layer is made of Cu.

In addition, the seed layer 55 is also interposed between the insulating layer 54 provided on the side surface 51a of the through-hole 51 and the via electrodes 52. In addition, the seed layer 55 is also interposed between the insulating layer 54 provided on the second main surface 50b of the second substrate 50 and the under bump metal 56.

In addition, the under bump metal 56 is provided at the via electrode 52 in the second thickness direction Z2. A bump 57 is laminated on the under bump metal 56 in the second thickness direction Z2.

In addition, a frame portion 40 surrounding the functional electrode 84A and the wiring layer 20 is provided between the other main surface 2a of the piezoelectric layer 2 and the first main surface 50a of the second substrate 50. The frame portion 40 seals portions between the piezoelectric layer 2 and the second substrate 50. The frame portion 40 includes a first frame layer 41, a second frame layer 42, a third frame layer 43, a fourth frame layer 44, and a fifth frame layer 45 that are laminated in order from the second thickness direction Z2. The first frame layer 41 is made of the same material as the etching stop layer 25. That is, the first frame layer 41 is formed on the second substrate 50 simultaneous with the etching stop layer 25. In addition, the second frame layer 42 is made of the same material as the first wiring layer 23. That is, the second frame layer 42 is formed on the second substrate 50 simultaneous with the first wiring layer 23.

Similarly, the third frame layer 43 is made of the same material as the second wiring layer 22, and is formed on the first substrate 8A simultaneous with the second wiring layer 22. Thus, the second frame layer 42 and the third frame layer 43 are bonded to each other by Au—Au bonding, as in the case of the first wiring layer 23 and the second wiring layer 22. A third frame portion 33 is made of the same material as the intermediate wiring layer 21, and is a layer formed simultaneous with the intermediate wiring layer 21. A fourth frame portion 34 is made of the same material as the functional electrode 84A, and is a layer formed simultaneous with the functional electrode 84A.

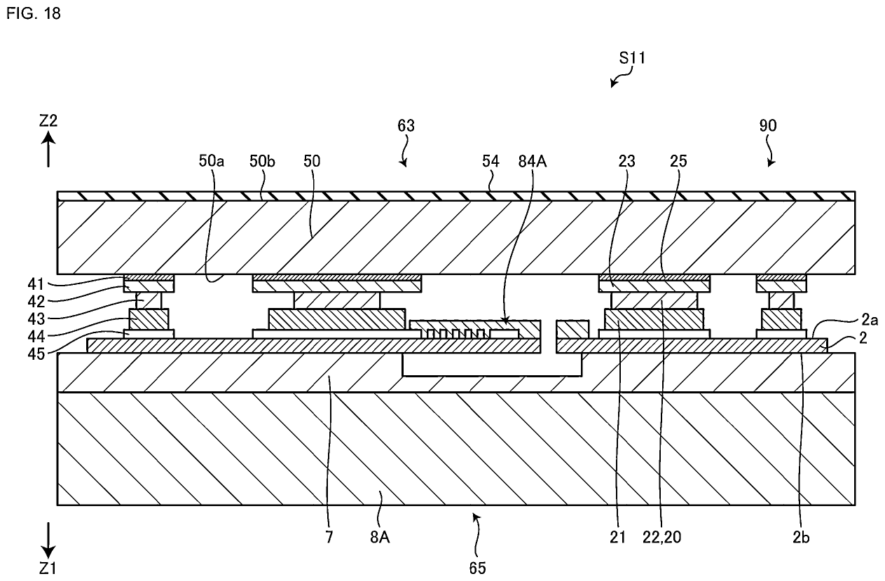

Next, an example of a method of manufacturing the acoustic wave device of an example embodiment will be described. The method of manufacturing the acoustic wave device 1A includes, in the preparatory stage, a step of preparing a first substrate side intermediate product 65 (see FIG. 18) and a step of preparing a second substrate side intermediate product 63 (see FIG. 18). In addition, the step of preparing the second substrate side intermediate product includes a resist film forming step S1, an etching stop layer forming step S2, a first wiring layer forming step S3, and a resist film removing step S4.

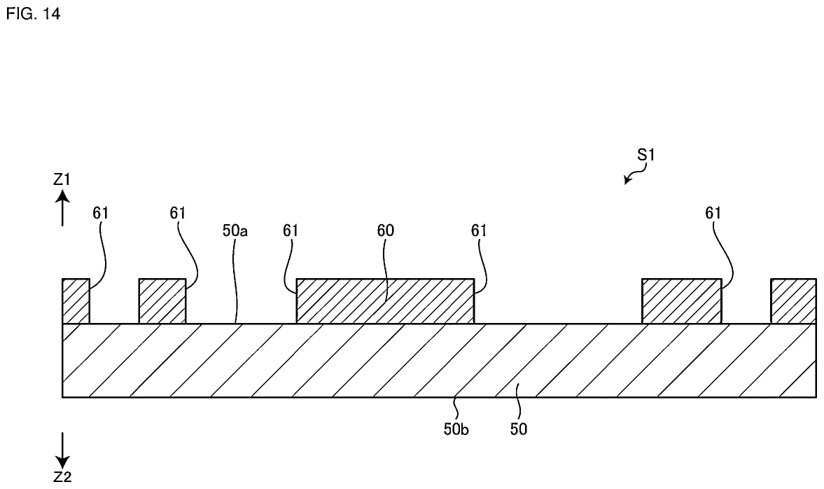

FIG. 14 is a cross-sectional view illustrating the second substrate after the resist film forming step of the present example embodiment. As illustrated in FIG. 14, the resist film forming step S1 is a step of forming a resist film 60 having an opening portion 61 on the first main surface 50a of the second substrate 50. In addition, the opening portion 61 is provided in a region where the etching stop layer 25 is formed and a region where the first frame layer 41 is formed.

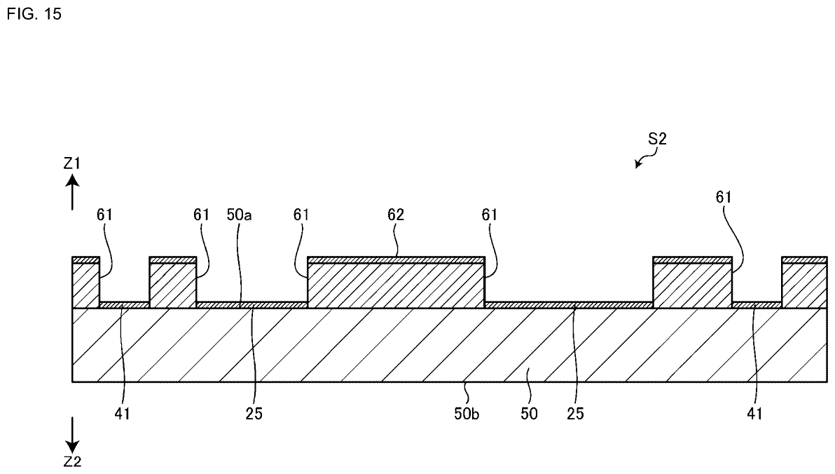

FIG. 15 is a cross-sectional view illustrating the second substrate after the etching stop layer forming step of the present example embodiment. As illustrated in FIG. 15, the etching stop layer forming step S2 is a step of depositing a metal material 62 on the resist film 60. Note that in the present example embodiment, the metal material is any one of Ti, AlCu, Pt, and Cu. By this step, the etching stop layer 25 and the first frame layer 41 are laminated on the first main surface 50a of the second substrate 50 via the opening portion 61.

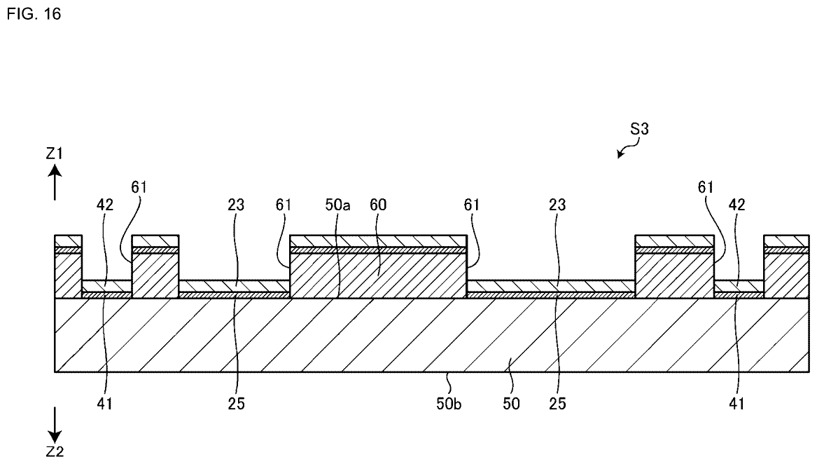

FIG. 16 is a cross-sectional view illustrating the second substrate after the first wiring layer forming step of the present example embodiment. As illustrated in FIG. 16, the first wiring layer forming step S3 is a step of laminating the first wiring layer 23, which is a portion of the wiring layer 20, on the resist film 60. In the present example embodiment, Ti, Pt, and Au are laminated in this order. By this step, the first wiring layer 23 is laminated on the etching stop layer 25 via the opening portion 61. In addition, the second frame layer 42 is laminated on the first frame layer 41 via the opening portion 61. Note that the first wiring layer 23 includes a Ti layer, a Pt layer, and an Au layer.

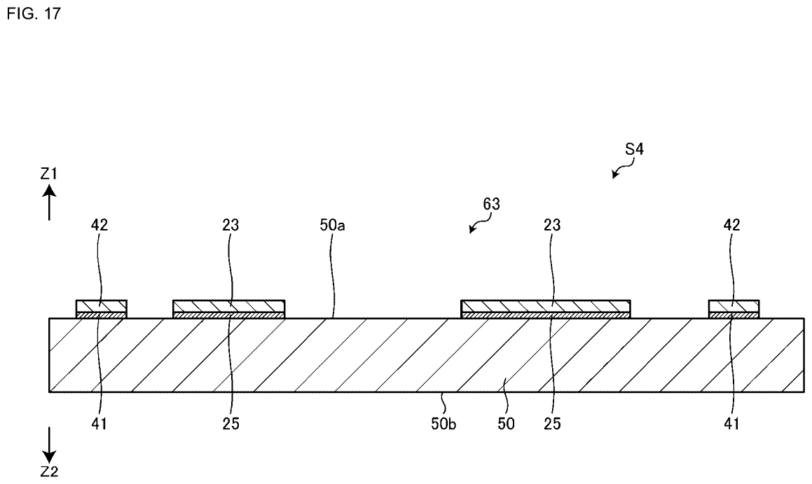

FIG. 17 is a cross-sectional view illustrating the second substrate after the resist film removing step of the example embodiment. As illustrated in FIG. 17, the resist film removing step S4 is a step of removing the resist film 60. By this step, the second substrate side intermediate product 63 is manufactured, and the step of preparing the second substrate side intermediate product 63 is finished. Note that the description of the step of preparing the first substrate side intermediate product 65 is omitted.

The method of manufacturing the acoustic wave device 1A includes, as steps after the preparatory stage is finished, a bonding step S11, a through-hole forming step S12, an insulating film forming step S13, a seed layer laminating/resist film forming/plate processing step S14, a resist film removing/window forming step S15, a dicing step S16, a soldering step S17, and a singulation/polishing step S18.

FIG. 18 is a cross-sectional view illustrating an intermediate product after the bonding step of the present example embodiment. As illustrated in FIG. 18, the bonding step S11 is a step of bonding the first substrate side intermediate product 65 and the second substrate side intermediate product 63.

The first substrate side intermediate product 65 includes the first substrate 8A, the piezoelectric layer 2, and a portion of the wiring layer 20 laminated on the other main surface 2a of the piezoelectric layer 2. The portion of the wiring layer 20 is the intermediate wiring layer 21 and the second wiring layer 22. Note that the third frame layer 43, the fourth frame layer 44, and the fifth frame layer 45, which are portions of the frame portion 40, are laminated on the other main surface 2a of the piezoelectric layer 2.

In the bonding step S11, first, the second wiring layer 22 of the first substrate side intermediate product 65 and the first wiring layer 23 of the second substrate side intermediate product 63 are arranged so as to overlap each other. In addition, the third frame layer 43 of the first substrate side intermediate product 65 and the second frame layer 42 of the second substrate side intermediate product 63 are arranged so as to overlap each other. Thereafter, the second wiring layer 22 (Au layer) and the Au layer of the first wiring layer 23 are bonded by Au—Au bonding. In addition, the third frame layer 43 (Au layer) and the Au layer of the second frame layer 42 are bonded by Au—Au bonding. Thus, as illustrated in FIG. 18, an intermediate product 90 in which the first substrate 8A and the second substrate 50 are integrated is manufactured.

In addition, after the bonding step, the insulating layer 54 is formed on the second main surface 50b of the second substrate 50. As a method of forming the insulating layer 54, for example, tetra ethoxy silane (TEOS) is adopted. Note that when manufacturing the acoustic wave device 1A, a large number of acoustic wave devices 1A are manufactured at once. That is, the intermediate product 90 illustrated in FIG. 18 is a part (one) of an aggregated intermediate product in which the plurality of intermediate products 90 is aggregated. In addition, the intermediate product 90 may be referred to as an object.

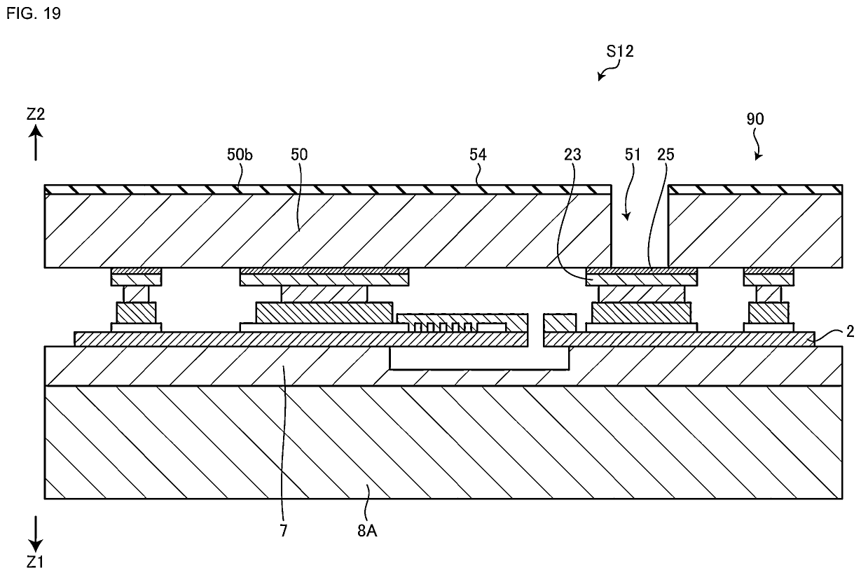

FIG. 19 is a cross-sectional view illustrating the intermediate product after the through-hole forming step of the example embodiment. As illustrated in FIG. 19, the through-hole forming step S12 is a step of forming the through-hole 51 in the second substrate 50 of the intermediate product (object) 90 by dry etching. As the gas used in the through-hole forming step S12, any of C4F8 gas, CF4 gas, CHF3 gas, or SF6 gas is used.

In the through-hole forming step S12, the through-hole 51 is formed in the second main surface 50b of the second substrate 50 in a range overlapping the etching stop layer 25 in plan view. In addition, in order to make the shape and depth of the through-hole 51 constant, it is performed under the over-etching condition. In addition, even when it is performed under the over-etching condition, the etching stop layer 25 is formed of any one of Ti, AlCu, Pt, and Cu. That is, the etching rate of the etching stop layer 25 is low, and no through-hole is formed in the etching stop layer 25. Therefore, no hole is formed in the first wiring layer 23.

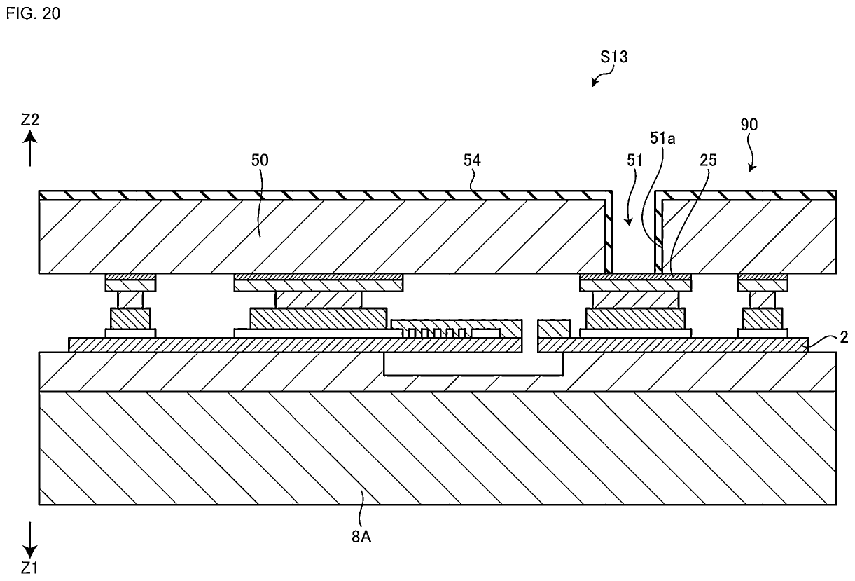

FIG. 20 is a cross-sectional view illustrating the intermediate product after the insulating film forming step of the example embodiment. As illustrated in FIG. 20, the insulating film forming step S13 is a step of forming the insulating layer 54 on the side surface 51a of the through-hole 51.

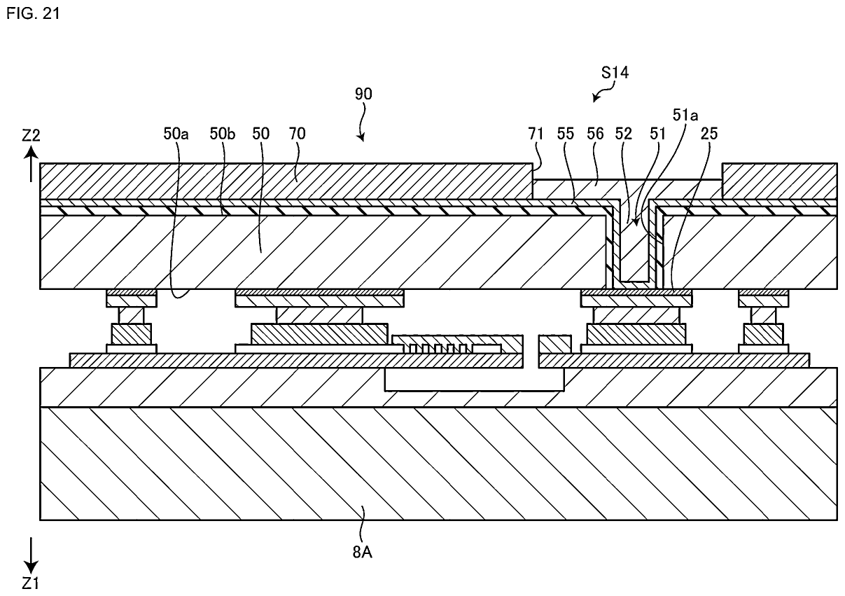

FIG. 21 is a cross-sectional view illustrating the intermediate product after the seed layer laminating/resist film forming/plate processing step of the present example embodiment. As illustrated in FIG. 21, the seed layer laminating/resist film forming/plate processing step S14 is a step of forming the seed layer 55, then forming the resist film, and then performing the plate processing. Note that the step of laminating the seed layer 55 in the seed layer laminating/resist film forming/plate processing step S14 may be referred to as a seed layer forming step.

In the seed layer forming step, portions where the seed layer 55 is laminated are the insulating layer 54 provided on the second main surface 50b of the second substrate 50, the side surface 51a (inner peripheral side of the insulating layer 54) of the through-hole 51, and the bottom surface (etching stop layer 25) of the through-hole 51. In addition, when the seed layer 55 is formed of the first metal layer and the second metal layer, the seed layer forming step includes a first laminating step of laminating the first metal material on the etching stop layer 25 and a second laminating step of laminating the second metal material on the layer of the first metal material. In addition, in the first laminating step, as described above, from the viewpoint of adhesion and low resistance, the first metal layer of the seed layer 55 is preferably formed of the same metal material as the etching stop layer 25 or Ti.

In addition, in the seed layer laminating/resist film forming/plate processing step S14, the resist film 70 is laminated on the seed layer 55 laminated on the second main surface 50b in the second thickness direction Z2. In addition, the resist film 70 is provided with the opening portion 71. The opening portion 71 exposes the through-hole 51 and the periphery of the opening of the through-hole 51 in the second thickness direction Z2.

In the seed layer laminating/resist film forming/plate processing step S14, a portion on which the plate processing is performed is a portion exposed from the opening portion 71 of the resist film 70. Further, before the plate processing is performed, it is preferable to perform surface treatment on the portion exposed from the opening portion 71 of the resist film 70 by a PR method. The plate processing is performed in the order of Au, Ti, and Cu. As a result, the via electrode 52 is formed in the through-hole 51. In addition, the under bump metal 56 is formed in the opening portion 71.

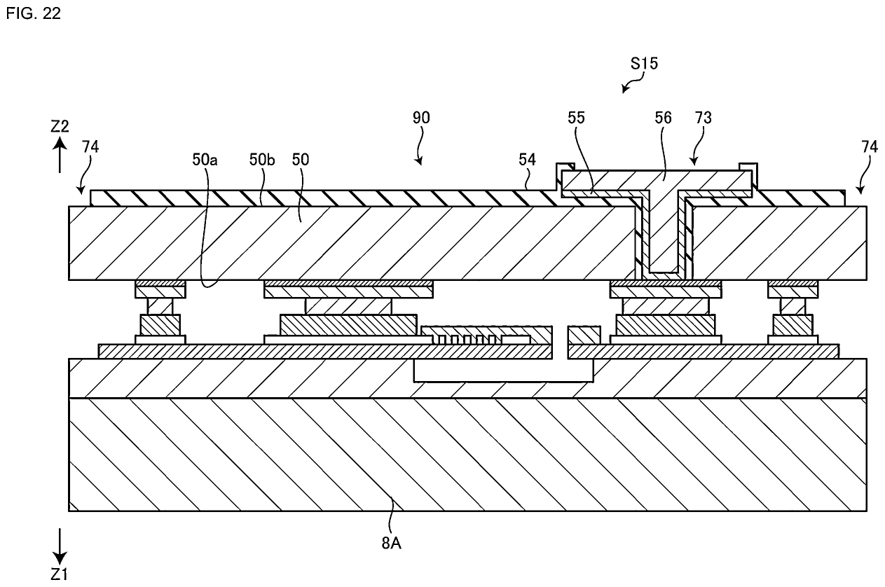

FIG. 22 is a cross-sectional view illustrating the intermediate product after the resist film removing/window forming step of the present example embodiment. As illustrated in FIG. 22, the resist film removing/window forming step S15 is a step of removing the resist film 70 and then forming a bump window 73 and a dicing window 74. When the resist film 70 is removed, an excess portion of the seed layer 55 is removed together. Note that the excess portion of the seed layer 55 is the seed layer 55 laminated on the insulating layer 54 on the second main surface 50b.

In the forming method of the bump window 73 and the dicing window 74, a resist layer (not illustrated) is provided at portions where the bump window 73 and the dicing window 74 are to be formed, and an insulating film is formed on the resist layer. Thereafter, the resist layer is removed. According to this, the portion where the resist layer is provided becomes an opening portion which is not covered with the insulating layer. In addition, the central portion of the under bump metal 56 in the second thickness direction Z2 is exposed by the bump window 73. Further, the boundary, on the second main surface 50b of the second substrate 50, between the plurality of intermediate products 90 is exposed by the dicing window 74.

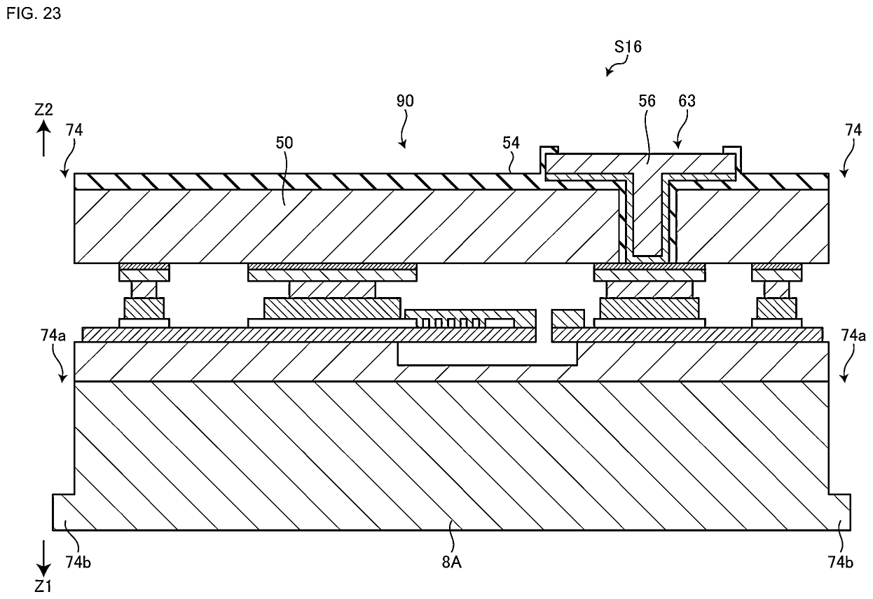

FIG. 23 is a cross-sectional view illustrating the intermediate product after the dicing step of the present example embodiment. As illustrated in FIG. 23, the dicing step S16 is a step of performing cutting in the thickness direction by dicing. Specifically, the second substrate 50 is cut by cutting a portion of the second substrate 50 exposed from the dicing window 74. After the second substrate 50 is cut, the first substrate 8A is also cut in a range overlapping the dicing window 74, and a cut 74a is formed in the first substrate 8A. According to this, the plurality of intermediate products 90 is connected to each other via a coupling portion 74b (a portion of the first substrate 8A).

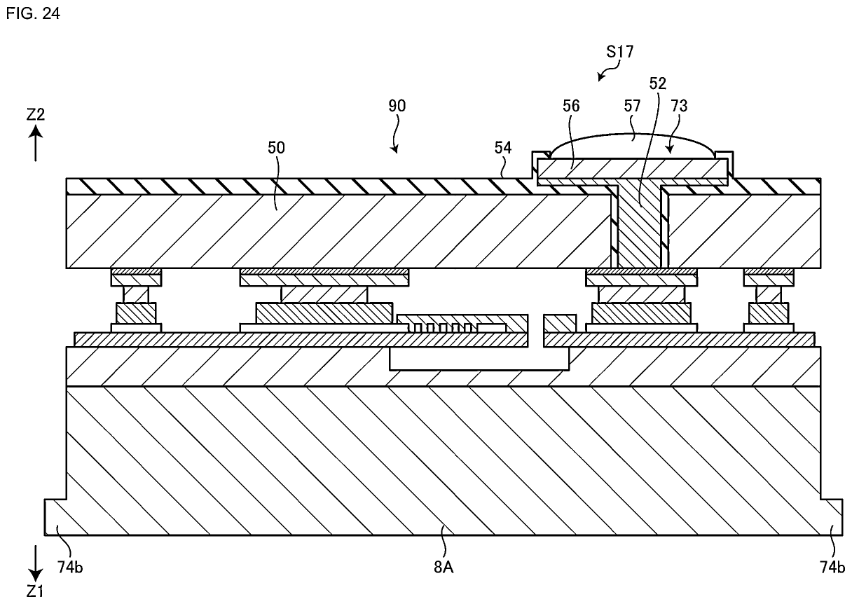

FIG. 24 is a cross-sectional view of the intermediate product after soldering of the present example embodiment. The soldering step S17 is a step of printing solder on a portion of the under bump metal 56 exposed from the bump window 73 and then flowing the solder to form the bump 57.

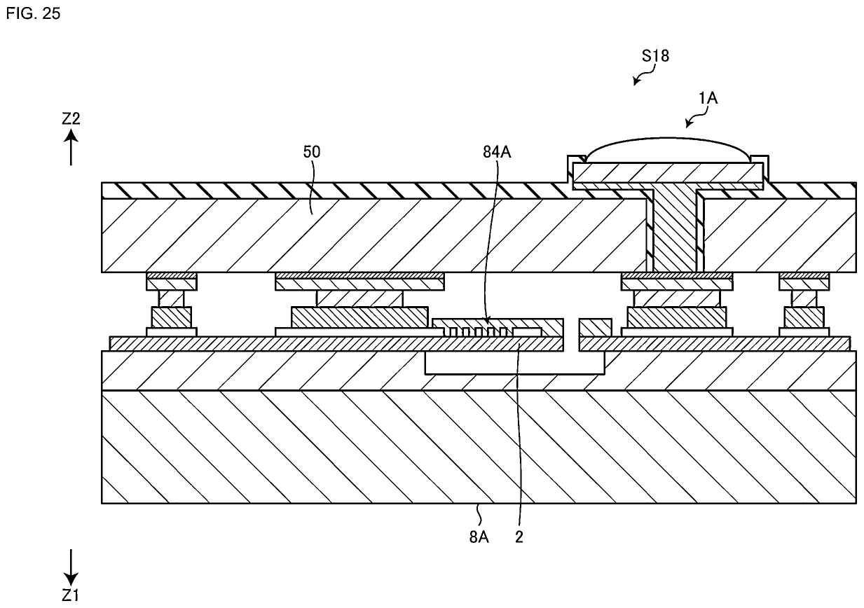

FIG. 25 is a cross-sectional view of the acoustic wave device after the singulation/polishing step of the present example embodiment. As illustrated in FIG. 25, the singulation/polishing step S18 is a step of dividing the intermediate product 90 into individual pieces by cutting a coupling portion 74b and then polishing the first substrate 8A. The first substrate 8A is polished from the surface of the first substrate 8A in the first thickness direction Z1 to such an extent that the coupling portion 74b does not remain. Thus, the plurality of acoustic wave devices 1A is manufactured, and the method of manufacturing the acoustic wave device 1A is completed.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a first substrate;
a piezoelectric layer including one main surface and another main surface facing a thickness direction of the first substrate, the one main surface facing the first substrate;
a functional electrode provided on at least one of the one main surface and the another main surface of the piezoelectric layer;
a second substrate including a first main surface and a second main surface facing the thickness direction and a through-hole penetrating from the first main surface to the second main surface, the first main surface facing the another main surface of the piezoelectric layer;
a via electrode in the through-hole;
a wiring layer between the piezoelectric layer and the second substrate and electrically connecting the functional electrode and the via electrode; and
an etching stop layer between the via electrode and the wiring layer; wherein
the etching stop layer includes a metal material with an etching rate lower than an etching rate of the second substrate.

2. The acoustic wave device according to claim 1, wherein
the second substrate is a silicon substrate; and
an etching rate of the etching stop layer in any one of C4F8 gas, CF4 gas, CHF3 gas, or SF6 gas is lower than an etching rate of the second substrate.

3. The acoustic wave device according to claim 1, wherein
the wiring layer includes a first wiring layer and a second wiring layer laminated in order from a second substrate side; and
the etching stop layer and the first wiring layer overlap each other in the thickness direction.

4. The acoustic wave device according to claim 1, wherein
a seed layer including a plurality of metal materials is between the via electrode and the etching stop layer in the through-hole;
the seed layer includes:
a first metal layer laminated on the etching stop layer; and
a second metal layer laminated on the first metal layer; and
the first metal layer is made of a same metal material as the etching stop layer.

5. The acoustic wave device according to claim 1, wherein
a seed layer including a plurality of metal materials is between the via electrode and the etching stop layer in the through-hole;
the seed layer includes:
a first metal layer laminated on the etching stop layer; and
a second metal layer laminated on the first metal layer; and
the first metal layer is made of Ti.

6. An acoustic wave device comprising:
a first substrate;
a piezoelectric layer including one main surface and another main surface facing a thickness direction of the first substrate, the one main surface facing the first substrate;
a functional electrode provided on at least one of the one main surface and the another main surface of the piezoelectric layer;
a second substrate being a silicon substrate and including a first main surface and a second main surface facing the thickness direction and a through-hole penetrating from the first main surface to the second main surface, the first main surface facing the another main surface of the piezoelectric layer;
a via electrode in the through-hole;
a wiring layer between the piezoelectric layer and the second substrate and electrically connecting the functional electrode and the via electrode; and
an etching stop layer between the via electrode and the wiring layer; wherein
a metal material of the etching stop layer is any one of Ti, AlCu, Pt, or Cu.

7. The acoustic wave device according to claim 6, wherein
the wiring layer includes a first wiring layer and a second wiring layer laminated in order from a second substrate side; and
the etching stop layer and the first wiring layer overlap each other in the thickness direction.

8. The acoustic wave device according to claim 6, wherein
a seed layer including a plurality of metal materials is between the via electrode and the etching stop layer in the through-hole;
the seed layer includes:
a first metal layer laminated on the etching stop layer; and
a second metal layer laminated on the first metal layer; and
the first metal layer is made of a same metal material as the etching stop layer.

9. The acoustic wave device according to claim 6, wherein
a seed layer including a plurality of metal materials is between the via electrode and the etching stop layer in the through-hole;
the seed layer includes:
a first metal layer laminated on the etching stop layer; and
a second metal layer laminated on the first metal layer; and
the first metal layer is made of Ti.

10. A method of manufacturing an acoustic wave device comprising:
forming a through-hole in an object by dry etching; wherein
the object includes:
a first substrate;
a piezoelectric layer including one main surface and another main surface facing a thickness direction of the first substrate, the one main surface facing the first substrate;
a functional electrode provided on at least one of the one main surface and the another main surface of the piezoelectric layer;
a second substrate including a first main surface and a second main surface facing the thickness direction, the first main surface facing the another main surface of the piezoelectric layer;
a wiring layer between the piezoelectric layer and the second substrate; and
an etching stop layer between the wiring layer and the first main surface and including a metal material with an etching rate lower than an etching rate of the second substrate; and
the through-hole is formed in the second main surface of the second substrate to at least partially overlap the etching stop layer in plan view.

11. The method of manufacturing an acoustic wave device according to claim 10, wherein
the second substrate is a silicon substrate; and
gas used in the through-hole forming step is any one of C4F8 gas, CF4 gas, CHF3 gas, or SF6 gas.

12. The method of manufacturing an acoustic wave device according to claim 10, further comprising:
forming a resist film by forming a resist including an opening portion on the first main surface of the second substrate;
forming an etching stop layer by depositing a metal material on the resist to generate an etching stop layer on the first main surface via the opening portion;
forming a first wiring layer by laminating a first wiring layer, which is a portion of the wiring layer, on the opening portion;
removing the resist; and
bonding a second wiring layer of a first substrate side intermediate product including the first substrate, the piezoelectric layer, and the second wiring layer which is laminated on the another main surface of the piezoelectric layer and is a portion of the wiring layer, and the first wiring layer.

13. The method of manufacturing an acoustic wave device according to claim 10, further comprising:
forming a seed layer on the etching stop layer via the through-hole after the through-hole forming step by laminating a first metal material on the etching stop layer and laminating a second metal material on a layer of the first metal material;
wherein the first metal material is a same as a metal material of the etching stop layer.

14. The method of manufacturing an acoustic wave device according to claim 10, further comprising forming a seed layer on the etching stop layer via the through-hole after the through-hole forming step by laminating a first metal material on the etching stop layer and laminating a second metal material on a layer of the first metal material; wherein the first metal material is Ti.

15. A method of manufacturing an acoustic wave device comprising:
forming a through-hole in an object by dry etching; wherein
the object includes:
a first substrate;
a piezoelectric layer including one main surface and another main surface facing a thickness direction of the first substrate, the one main surface facing the first substrate;
a functional electrode provided on at least one of the one main surface and the another main surface of the piezoelectric layer;
a second substrate including a first main surface and a second main surface facing the thickness direction, the first main surface facing the another main surface of the piezoelectric layer;
a wiring layer between the piezoelectric layer and the second substrate; and
an etching stop layer arranged between the wiring layer and the first main surface and including a metal material of any of Ti, AlCu, Pt, or Cu; and
the through-hole is formed in the second main surface of the second substrate to at least partially overlap the etching stop layer in plan view.

16. The method of manufacturing an acoustic wave device according to claim 15, further comprising:
forming a resist film by forming a resist including an opening portion on the first main surface of the second substrate;
forming an etching stop layer by depositing a metal material on the resist to generate an etching stop layer on the first main surface via the opening portion;
forming a first wiring layer by laminating a first wiring layer, which is a portion of the wiring layer, on the opening portion;
removing the resist; and
bonding a second wiring layer of a first substrate side intermediate product including the first substrate, the piezoelectric layer, and the second wiring layer which is laminated on the another main surface of the piezoelectric layer and is a portion of the wiring layer, and the first wiring layer.

17. The method of manufacturing an acoustic wave device according to claim 15, further comprising:
forming a seed layer on the etching stop layer via the through-hole after the through-hole forming step by laminating a first metal material on the etching stop layer and laminating a second metal material on a layer of the first metal material;
wherein the first metal material is a same as a metal material of the etching stop layer.

18. The method of manufacturing an acoustic wave device according to claim 15, further comprising forming a seed layer on the etching stop layer via the through-hole after the through-hole forming step by laminating a first metal material on the etching stop layer and laminating a second metal material on a layer of the first metal material; wherein the first metal material is Ti.
